(19) United States
(12) Patent Application Publication
(10) Pub. No.: US 2020/0035495 A1
(43) Pub. Date: Jan. 30, 2020

(54) CHEMICAL-MECHANICAL POLISHING WITH VARIABLE-PRESSURE POLISHING PADS

(71) Applicant: GLOBALFOUNDRIES Inc., Grand Cayman (KY)

(72) Inventors: Dewei Xu, Clifton Park, NY (US); Lili Cheng, Rexford, NY (US); Shinichiro Kakita, Clifton Park, NY (US); Ushasree Katakamsetty, Singapore (SG); Roderick A. Augur, Saratoga Springs, NY (US)

(21) Appl. No.: 16/045,111

(22) Filed: Jul. 25, 2018

(51) Int. Cl. H01L 21/304; H01L 21/306; H01L 21/67; B24B 37/005

(52) U.S. Cl. CPC H01L 21/304; H01L 21/30625; B24B 37/005; H01L 21/67092; H01L 21/67253

(57) ABSTRACT

Apparatus and methods of chemical-mechanical polishing of a layer on a wafer. A plurality of polishers arranged on a rotating plate, and a carrier is configured to hold the wafer and to place the layer in contact with the polishers. Each polisher includes a platen and a force-applying device operatively connected to the platen, and the force-applying device is configured to apply a variable force to the platen in order to change a rate of material removal over an area of the layer on the wafer contacted by a polishing pad carried by the platen.

### BACKGROUND

The present invention relates to chemical-mechanical polishing and, more specifically, to chemical-mechanical polishing apparatus and methods for polishing a layer on a wafer.

Chemical-mechanical polishing (CMP) processes are used at one or more stages of integrated circuit fabrication to polish a layer on a wafer. Generally, a CMP tool includes a polishing pad mounted on a rotatable platen, a slurry feed that dispenses an abrasive polishing slurry onto the rotating polishing pad, and a carrier head arranged over the platen. The carrier head presses the wafer into contact with the polishing pad and spins the wafer relative to the rotating platen and polishing pad.

Conventional CMP tools employ a single polishing pad and platen that are each much larger than the wafer undergoing polishing. Localized topographies reflecting dishing and erosion may be produced during CMP as a result of variations in layout pattern densities. These localized surface topography variations may generate lithography printability defects because the depth of focus in the lithography tool cannot compensate for the height differences resulting from the localized surface topography variations. These localized surface topography variations may also produce unwanted variations in features, such as variations in the height of wires formed in a dielectric layer of an interconnect metallization level or the thickness of a plate of a metal-insulator-metal capacitor.

Improved chemical-mechanical polishing apparatus and methods for polishing a layer on a wafer are thus needed.

### SUMMARY

In an embodiment of the invention, an apparatus is provided for polishing a layer on a wafer. The apparatus includes a drive system, a plate configured to be rotated by the drive system, a plurality of polishers arranged on the plate, and a carrier configured to hold the wafer and to place the layer in contact with the polishers. Each polisher includes a platen and a force-applying device operatively connected to the platen, and the force-applying device is configured to apply a variable force to the platen.

In another embodiment of the invention, a method is provided for polishing a layer of a wafer. The method includes rotating a plate including a plurality of polishers arranged with stationary positions on the plate, and contacting an area of the layer with a polishing pad carried on each polisher, while rotating the wafer relative to the plate, to perform a polishing process. The method further includes adjusting a pressure applied by the polishing pad of one or more of the polishers to the corresponding area contacted on the layer in order to individually adjust a rate of material removal from the layer by the polishing pad of the one or more of the polishers.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIG. 1 is a top view of a polishing apparatus in accordance with embodiments of the invention.

FIG. 2 is a cross-sectional view taken generally along line 2-2 in FIG. 1.

FIG. 3 is a diagrammatic view of one type of pressure actuator for a polisher in accordance with embodiments of the invention.

FIG. 4 is a diagrammatic view of another type of pressure actuator for a polisher in accordance with embodiments of the invention.

FIG. 5 is a cross-section view of a polishing apparatus in accordance with alternative embodiments of the invention.

FIG. 6 is a diagrammatic view of a controller for controlling the operation of the polishing apparatus in accordance with embodiments of the invention.

### DETAILED DESCRIPTION

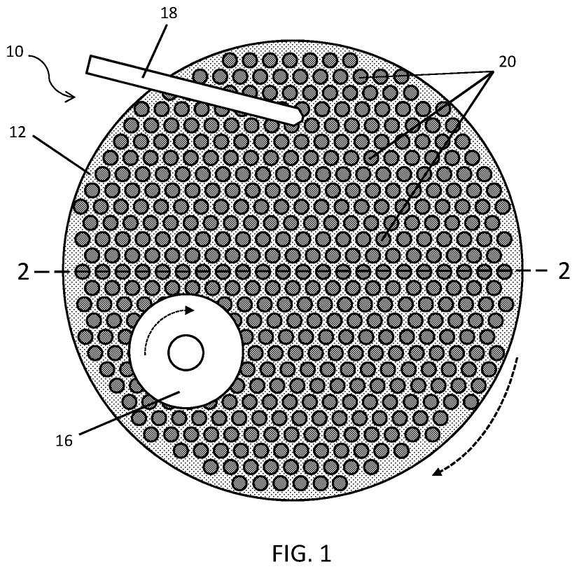

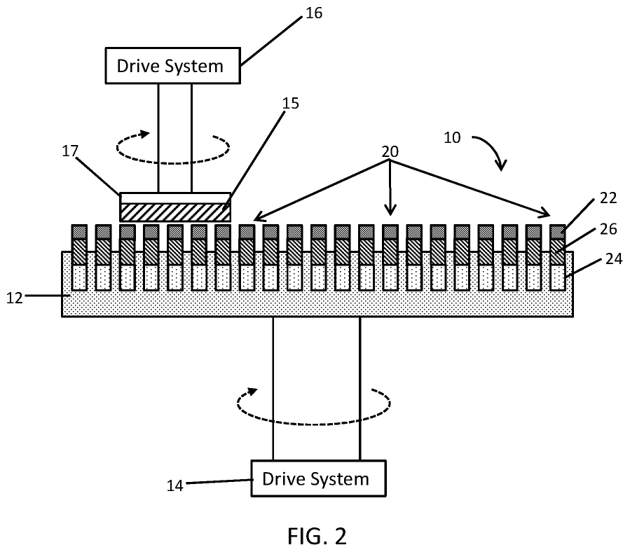

With reference to FIGS. 1, 2 and in accordance with embodiments of the invention, a polishing apparatus 10 for use in chemical-mechanical polishing processes includes a plate 12, a slurry/rinse arm 18 that is arranged with a nozzle over the plate 12, and polishers 20 that are coupled with the plate 12. The plate 12 is configured to be rotated, as indicated by the single-headed arrows in FIGS. 1 and 2, by a drive system 14 during a polishing process performed by the polishing apparatus 10. The plate 12 may be disk-shaped, and the drive system 14 may include a motor configured to turn a drive shaft to rotate the plate 12. The polishers 20 have fixed positions on the plate 12 and rotate with the plate 12 when the plate 12 is rotated. During a polishing process, the slurry/rinse arm 18 may dispense a polishing fluid, such as a slurry, or another fluid or liquid, such as a rinse solution, onto the plate 12 and polishers 20.

A carrier head 17 is arranged over the plate 12 and is configured to secure and hold a wafer 15. The carrier head 17 is positioned relative to the plate 12 to suspend the wafer 15 at a location that is inside the outer perimeter of the plate 12 and that is offset radially outwardly relative to the center of the plate 12. The carrier head 17 is configured to place the wafer 15 in contact with the polishers 20. The carrier head 17 is configured to be rotated, as indicated by the single-headed arrows in FIGS. 1 and 2, by a drive system 16 during a polishing process performed by the polishing apparatus 10. The drive system 16 may include a motor configured to turn a drive shaft to rotate the carrier head 17, which in turn rotates or spins the wafer 15 during a polishing process. In an embodiment, both the plate 12 and the carrier head 17 may be spun in a clockwise direction during a polishing process. The carrier head 17 may be configured to provide a constant load that presses the wafer 15 against the polishers 20.

The polishers 20 are arranged in an array on the plate 12 and have fixed, stationary positions relative to the plate 12 and are not individually rotated about their respective axes of rotation. Each polisher 20 includes a polishing pad 22, a force-applying device 24, and a platen 26 that operatively connects the polishing pad 22 to the force-applying device 24. Each polishing pad 22, in conjunction with the abrasive slurry, is configured to remove material from a contacted area of a layer on the wafer 15. Each of the polishing pads 22 may have round wafer-contacting surface with an area having a diameter of less than or equal to 1 millimeter. Alternatively, the wafer-contacting surface may have a different shape with commensurate dimensioning. In general, the sizes of the polishing pads 22 may be determined based on a distribution of statistical size distributions of local surface topographies of the layer on the wafer 15. The polishing pads 22 may be detachably secured to the platens 26, such as by an adhesive layer, which may permit the the polishing pads 22 to be removed from the platens 26 and individually replaced. In an alternative embodiment, polishing pads 22 may be non-detachably secured to the platens 26 such that the plate 12 and array of polishers 20 can be removed and replaced as a unitary assembly.

The force-applying device 24 of each polisher 20 is capable of applying an independently-variable force to the polishing pad 22 and platen 26 that is transferred from the polishing pad 22 to an area of a layer on the wafer 15 as a correspondingly independently-variable pressure. The force applied by each of the force-applying devices 24 is capable of being changed or varied independent of the force applied by the other force-applying devices 24. The ability to provide the independently-variable pressures during a polishing process is promoted by arraying multiple polishers 20 on the plate 12 that are each smaller than the wafer 15, instead of using a single polishing pad and platen that are significantly larger than the wafer 15 itself. The force-applying device 24 may respond to variations in layout pattern densities of the layer being polished by actively adapting the force applied by each polishing pad 22 and platen 26 during the polishing process to the level of local surface topography. The time-dependent adaptation may be effective to reduce unwanted dishing and erosion of the layer.

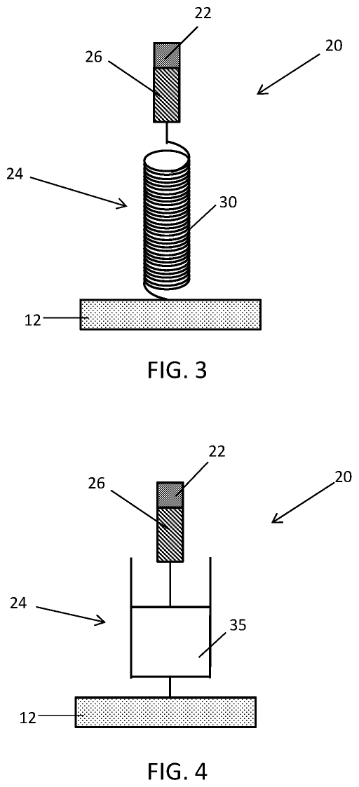

With reference to FIG. 3 in which like reference numerals refer to like features in FIGS. 1, 2, the force-applying device 24 of each polisher 20 may be a passive mechanism having the form of a spring device 30. In an embodiment, the spring device 30 may be a compression spring that is compressed from its unloaded free length between the platen 26 and a portion of the plate 12 such that the spring device 30 applies a force to the platen 26. The applied force resiliently biases the polishing pad 22 and platen 26 in a direction toward the area of the layer on the wafer 15 contacted by the polishing pad 22. The spring device 30 may include an end coil connected with the platen 26, an end coil connected with the plate 12, and a plurality of helically-wound active coils distributed with a given pitch between the opposite end coils.

Each spring device 30 is configured to resist an applied force by exerting an opposing force in direct proportion to the spring's displacement. The applied force causing displacement of each spring device 30 is directly proportional to the thickness or height of the area of the layer of the wafer 15 contacting the polishing pad 22 on the platen 26. In turn, the material removal rate associated with each polishing pad 22 and platen 26 is proportional to the force applied by the spring device 30 over the area of the polishing pad 22 (i.e., the applied pressure). During a polishing process, factors such as variations in layout pattern densities will cause variations in the material removal rate that produces areas on the layer of local surface topography with heights that are greater than an average height of all areas on the layer and areas on the layer of local surface topography with heights that are less than an average height of all areas on the layer. The spring device 30 can respond to these time-dependent variations in the local surface topography by adaptively adjusting the force applied to the polishing pad 22 and platen 26 so that the pressure applied by the polishing pad 22 to the contacted area on the layer is also adaptively adjusted.

A thicker area of a layer on a wafer 15 with a taller local surface topography in contact with the polishing pad 22 on each platen 26 will displace the spring device 30 by a greater amount than a contacted area of the layer with shorter local surface topography. Contacted areas of the layer on the wafer 15 that develop taller local topographies will thus have a comparatively higher pressure exerted against them by the polishing pads 22 and platens 26, and thus the associated spring devices 30 will respond by removing material removed at a higher or faster rate from these contacted areas by the polishing pad 22. A thinner contacted area of a layer on a wafer 15 with a shorter local surface topography in contact with the polishing pad 22 on each platen 26 will displace the spring device 30 by a lesser amount than a contacted area of the layer with taller local surface topography. Areas of the layer on the wafer 15 that develop shorter local topographies will thus have a comparatively lower pressure exerted against them by the polishing pads 22 and platens 26, and thus the associate spring devices 30 will respond by removing material at a lower or slower rate from these contacted areas by the polishing pad 22. During a polishing process and as the surface topography changes, the adaptive adjustments to the force applied by the spring devices 30 to the polishing pads 22 and platens 26 and the resulting pressure applied by the polishing pads 22 to the contacted areas of the layer on the wafer 15 may be effective to reduce erosion and dishing in each local surface topography and thereby improve the uniformity of the polishing process.

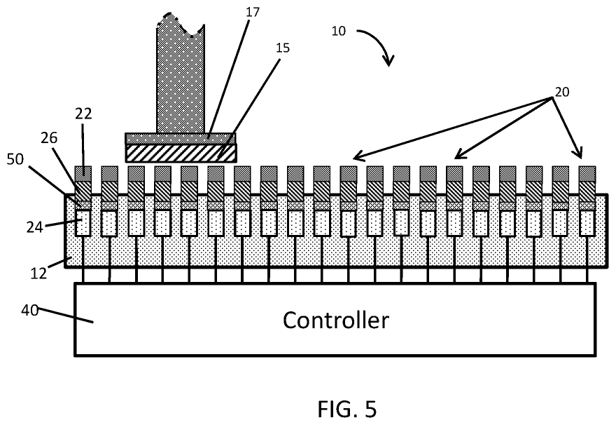

With reference to FIG. 4 in which like reference numerals refer to like features in FIGS. 1 and 2, the force-applying device 24 of each polisher 20 may be a passive mechanism having the form of a dashpot device 35. Each dashpot device 35 is a mechanical damper that resists motion by viscous friction, exerting a force opposing the motion in proportion to the magnitude of the motion, i.e. velocity of the motion. The dashpot device 35 of each polisher 20 thus exerts a force on the polishing pad 22 and platen 26 that is proportional to a change in the thickness or height of the contacted area of the layer on the wafer 15, rather than absolute thickness or height, during a polishing process. The dashpot device 35 responds to a contacted area of the layer on the wafer 15 that has a positive gradient indicating increasing thickness or height by applying a greater force to the polishing pad 22 and platen 26, which results in a higher pressure being applied to the area of the layer on the wafer 15 contacted by the polishing pad 22. The dashpot device 35 responds to a contacted area of the layer on the wafer 15 that has a negative gradient indicating decreasing thickness or height by applying a lesser force to the polishing pad 22 and platen 26, which results in a lower pressure being applied to the area of the layer on the wafer 15 contacted by the polishing pad 22.

With reference to FIG. 5 in which like reference numerals refer to like features in FIGS. 1 and 2, the force-applying device 24 of each polisher 20 may be an active device is connected with, and controlled by, a controller 40. Under the control of the controller 40, the force-applying device 24 of each polisher 20 is capable of applying a variable force to the platen 26 and polishing pad 22 that presses the polishing pad 22 against an area of the layer on the wafer 15 with a corresponding variable pressure determined by the controller 40. The force-applying device 24 may be a device, such as an actuator, that is configured to exert a force on the platen 26 and polishing pad 22 under automated control by the controller 40.

Each polisher 20 may further include a sensor 50 that is connected with the controller 40. Each sensor 50 is configured to measure a force or a pressure applied to each contacted area of the layer of the wafer 15, and output a stream of signals related to the measured force or pressure as feedback to the controller 40 for closed-loop control. For example, the sensor 50 may be a piezoelectric sensor that generates an electrical current as an output signal in response to the force or pressure, and transmits the electrical current as an analog stream of signals to the controller 40. Thus, contacted areas of the layer with thicker or taller local surface topography will exert a higher pressure, on average, against corresponding polishing pads 22 and platens 26 that causes the piezoelectric sensors 50 to generate larger currents on average. Conversely, contacted areas of the layer with thinner or shorter local surface topography will exert a lower pressure, on average, against the corresponding polishing pads 22 and platens 26 that causes the piezoelectric sensors 50 to generate smaller currents on average. The controller 40 is configured to determine the pressure applied to each polisher 20 at any instant in time based on the received signals, and may calculate a map of pressures related to the local topographies represented by a corresponding thickness or height of each area of the layer contacted by the polishing pads 22.

Based in part on a map of the pressures applied by each polisher 20 when contacting the layer on the wafer 15, the controller 40 can determine an adjustment to the force to be applied by the force-applying device 24 to the platen 26 and polishing pad 22 of each polisher 20, which adjusted force is communicated to the corresponding contacted area of the layer on the wafer 15 as an adjusted pressure. For example, the controller 40 may compute an average force or pressure sensed for all polishers 20 and adjust the individual forces applied by the force-applying devices 24 to reduce the deviation from the average force so that the pressures applied to the areas of the layer on the wafer contacted by the polishing pads 22 are more uniform. For example, the controller 40 may cause the force-applying devices 24 to extend or retract an arm of an actuator to respectively increase or reduce the force applied to the attached polishing pad 22 and platen 26 and the pressure applied to the area contacted by the polishing pad 22.

As polishing of the layer on the wafer 15 proceeds and material is removed from areas of the layer by the polishing pads 22, the height of areas of the layer on the wafer may change with different areas experiencing different rates of material removal. Each sensor 50 in the array of sensors 50 may detect the force or pressure applied by the corresponding platen 26 and polishing pad 22 to contacted areas of the layer on the wafer 15, and continuously or repeatedly relay the detected force or pressure to the controller 40 as described above. As the force or pressure detected by each sensor 50 changes, the controller 40 may accordingly adjust the variable force or pressure applied through force-applying device 24 to the corresponding polishing pad 22 and platen 26. Polishing may be terminated by the controller 40 when, for example, the forces or pressures applied to the different areas of the layer of the wafer 15, as analyzed from the map of pressures, reaches a targeted acceptable level of variation.

For example, the targeted pressure uniformity may be determined from a standard deviation of the pressures being applied by the array of polishers 20 and a comparison with a minimum acceptable standard deviation in pressure. One exemplary calculation for comparing average pressure to the minimum acceptable standard deviation in the pressures applied to the contacted areas of the layer on the wafer is:

$$\sqrt{\frac{{\sum }_{i = 1}^{N} ( {p}_{i} - \overline{p} )}{N - 1}} < {p}_{c} \qquad ( 1 )$$

where N is the number of polishers, p, is the pressure exerted by each individual polisher 20 as controlled via the controller 40, p̅ is the average pressure applied by the polishers 20, and p_{C} is a minimum acceptable standard deviation in the measured pressure. When the condition of equation 1 has been met and the standard deviation of the measured pressures is less than the minimum acceptable standard deviation in pressure that is targeted for the polishing process, the chemical-mechanical polishing process can be terminated because a minimum pressure variation has been achieved for the different polishers 20, which indicates that a minimum acceptable height or thickness uniformity has been achieved for the layer of the wafer 15.

In an embodiment, the polishing process performed by the polishing apparatus 10 may be preceded by a conventional polishing process performed by a conventional chemical-mechanical polishing system.

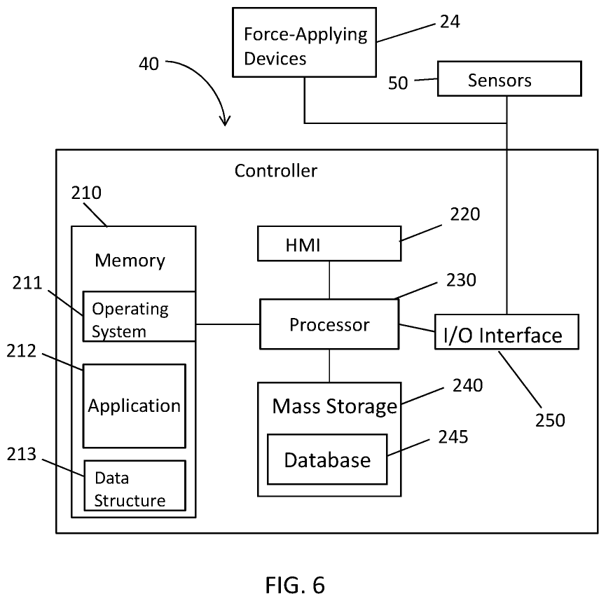

With reference to FIG. 6, the controller 40 includes one or more processors 230, a memory 210, and a mass storage memory device 240 that includes a database 245, one or more input/output (I/O) interfaces 250, and may include a Human Machine Interface (HMI) 220. The controller 40 is operatively coupled to the sensors 50 and the active force-applying structures 24 via an I/O interface 250. The one or more processors 230 include one or more devices selected from microprocessors, micro-controllers, digital signal processors, microcomputers, central processing units, field programmable gate arrays, programmable logic devices, state machines, logic circuits, analog circuits, digital circuits, or any other devices that manipulate signals (analog or digital) based on operational instructions that are stored in the memory 210. Memory 210 includes a single memory device or a plurality of memory devices including, but not limited to, read-only memory (ROM), random access memory (RAM), volatile memory, non-volatile memory, static random access memory (SRAM), dynamic random access memory (DRAM), flash memory, cache memory, or any other device capable of storing information. The mass storage memory device 240 includes data storage devices such as a hard drive, optical drive, tape drive, volatile or non-volatile solid state device, or any other device capable of storing information.

The one or more processors 230 operate under the control of an operating system 211 that resides in the memory 210. The operating system 211 manages processing resources so that computer program code embodied as one or more computer software applications, such as an application 212 residing in memory 210, has instructions executed by the one or more processors 230. In an alternative embodiment, the one or more processors 230 execute the application 212 directly, in which case the operating system 211 may be omitted. One or more data structures 213 may also reside in memory 210, and may be used by the one or more processors 230, operating system 211, and/or application 212 to store or manipulate data.

The I/O interface 250 operatively couples the one or more processors 230 to other devices and systems, such as the sensors 50 and the active force-applying structures 24 of the polishing apparatus 10. The controller 270 may include power electronics that are coupled with the active force-applying structures 24 (e.g., actuators) in order to drive movements of the active force-applying structures 24. The application 212, which includes program code with instructions for execution by one or more processors 230 to cause the polishing apparatus 10 to perform polishing processes, thereby works cooperatively with the sensors 50, active force-applying structures 24, and other elements of the polishing apparatus 10 by communicating via the I/O interface 250 to provide the various features, functions, applications, processes, or modules comprising embodiments of the invention. The application 212 has program code that is executed by, or otherwise relies on functions or signals provided by other system or network components external to the controller 200. Indeed, given the nearly endless hardware and software configurations possible, persons having ordinary skill in the art will understand that embodiments of the invention may include applications that are located externally to the controller 200, distributed among multiple computers or other external resources, or provided by computing resources (hardware and software) that are provided externally to controller 200.

The HMI 220, if included, is operatively coupled to the one or more processors 230 of controller 200 in a known manner to allow a user to interact directly with the controller 200. The HMI 220 may include video or alphanumeric displays, a touch screen, a speaker, and any other suitable audio and visual indicators capable of providing data to the user. The HMI 220 may also include input devices and controls such as an alphanumeric keyboard, a pointing device, keypads, pushbuttons, control knobs, microphones, etc., capable of accepting commands or input from the user and transmitting the entered input to the one or more processors 230.

A database 245 resides on the mass storage memory device 240, and may be used to collect and organize data used by the various systems and modules described herein. For example, the database 245 may be used to store, among other data, pressure maps, topological maps, and/or sensor readings. The database 245 may include data and supporting data structures that store and organize the data. In particular, the database 245 may be arranged with any database organization or structure including, but not limited to, a relational database, a hierarchical database, a network database, or combinations thereof. A database management system in the form of a computer software application executing as instructions on the one or more processors 230 may be used to access the information or data stored in records of the database 245 in response to a query, where a query may be dynamically determined and executed by the operating system 211, other applications 212, or one or more modules.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An apparatus for polishing a layer on a wafer, the apparatus comprising:
a drive system;
a plate configured to be rotated by the drive system;
a plurality of polishers arranged on the plate, each polisher including a platen and a force-applying device operatively connected to the platen, the force-applying device configured to apply a variable force to the platen; and
a carrier configured to hold the wafer and to place the layer in contact with the polishers.

2. The apparatus of claim 1 wherein the force-applying device of each polisher is a dashpot device.

3. The apparatus of claim 1 wherein the force-applying device of each polisher is a spring device.

4. The apparatus of claim 1 wherein the force-applying device of each polisher is an actuator.

5. The apparatus of claim 4 further comprising:
a controller coupled with the actuator of each polisher,
wherein the controller is configured to cause the actuator of each polisher to be operated to provide the variable force.

6. The apparatus of claim 5 wherein each polisher includes a sensor coupled with the controller, and the sensor is configured to generate a signal in response to a pressure applied by an area contacted on the wafer to the platen and to provide the signal as feedback to the controller for closed-loop control.

7. The apparatus of claim 6 wherein the controller includes one or more processors and a memory coupled with the one or more processors, the memory including instructions that, when executed by the one or more processors, cause the apparatus to:
construct a map of the pressure sensed by the sensor of each polisher;
determine adjustments to a force applied by the actuator of one or more of the polishers based on the map; and
operating the actuator connected with the one or more of the polishers to implement the adjustments to the force.

8. The apparatus of claim 6 wherein the sensor is a piezoelectric sensor.

9. The apparatus of claim 7 wherein the polishers are arranged in an array such that the map of the pressure reflects a position of the sensor of each polisher in the array.

10. The apparatus of claim 1 wherein each polisher further comprises a polishing pad connected to the platen, the polishing pad configured to contact an area of the layer on the wafer.

11. The apparatus of claim 10 wherein the polishing pad is detachably connected to the platen.

12. The apparatus of claim 10 wherein the polishing pad is disk shaped with a diameter of about less than or equal to one millimeter.

13. A method for polishing a layer of a wafer, the method comprising:
rotating a plate including a plurality of polishers arranged with stationary positions on the plate;
contacting an area of the layer with a polishing pad carried on each polisher while rotating the wafer relative to the plate to perform a polishing process; and
adjusting a pressure applied by the polishing pad of one or more of the polishers to the corresponding area contacted on the layer in order to individually adjust a rate of material removal from the layer by the polishing pad of the one or more of the polishers.

14. The method of claim 13 wherein adjusting the pressure applied by the polishing pad of the one or more of the polishers to the corresponding area contacted on the layer comprises:
adjusting a variable force applied from a force-applying device to one or more of the polishers based on displacement of a spring.

15. The method of claim 13 wherein adjusting the pressure applied by the polishing pad of the one or more of the polishers to the corresponding area contacted on the layer comprises:
adjusting a variable force applied from a force-applying device to one or more of the polishers based on a rate change of a displacement of a dashpot.

16. The method of claim 13 wherein each polisher is mechanically connected with an actuator, and adjusting the pressure applied by the polishing pad of the one or more of the polishers to the corresponding area contacted on the layer comprises:
adjusting a variable force applied to one or more of the polishers from the respective actuator.

17. The method of claim 16 further comprising:
measuring a sensed force or a sensed pressure applied to each polisher by the area contacted on the layer; and
adjusting the pressure applied by the polishing pad of the one or more of the polishers to the corresponding area contacted on the layer based on the sensed force or the sensed pressure.

18. The method of claim 17 wherein the sensed force or the sensed pressure is measured by a sensor associated with each polisher, the actuator and the sensor of each polisher is coupled with a controller, the sensed force or the sensed pressure is provided as a control signal providing feedback to the controller, and the variable force is applied from the respective actuator to one or more of the polishers based on closed-loop control by the controller.

19. The method of claim 18 wherein the polishers are arranged in an array, and further comprising:
generating, by one or more processors of the controller, a map of the sensed force or the sensed pressure received from the sensor associated with each of the polishers.

20. The method of claim 19 further comprising:
determining that a targeted deviation of the sensed pressure or the sensed force is achieved based on the map; and
terminating the polishing of the wafer upon determining that the targeted deviation of the sensed force or the sensed pressure has been achieved.
